(19) United States
(12) Patent Application Publication
(10) Pub. No.: US 2006/0152151 A1
(43) Pub. Date: Jul. 13, 2006

(54) Organic light emitting display with color filter layer

(76) Inventor: Seong-Moh Seo, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/297,708

(22) Filed: Dec. 8, 2005

(30) Foreign Application Priority Data
Dec. 10, 2004 (KR) 10-2004-0104477

(51) Int. Cl. H05B 33/00

(52) U.S. Cl. 313/506; 313/504

(57) ABSTRACT

An organic light emitting display and a method of fabricating the same are provided. The organic light emitting display includes: a substrate having a plurality of pixel regions; a thin film transistor formed at each pixel region of the substrate and including a semiconductor layer, a gate electrode, and source and drain electrodes; a color filter layer formed on the transistor at each pixel region; a first electrode patterned to be in contact with one of the source and drain electrodes of the thin film transistor through a via-hole in the color filter layer; a pixel defining layer having an opening formed to expose a portion of the first electrode; an emission layer formed on the exposed first electrode; and a second electrode formed on the emission layer over the substrate. Therefore, it is possible to simplify the process by forming the color filter layers between the thin film transistor and the first electrode, without a passivation layer, increase process stability by increasing alignment margin between upper and lower substrates when the color filter layer is adhered, and facilitate top and bottom emission.

### CROSS-REFERENCE TO RELATED APPLICATIONS

This application claims priority to and the benefit of Korean Patent Application No. 10-2004-0104477, filed Dec. 10, 2004, which is incorporated herein by reference in its entirety.

### BACKGROUND OF THE INVENTION

1. Field of the Invention

The present invention relates to an organic light emitting display, and more particularly, to an organic light emitting display having a color filter layer between a thin film transistor and a first electrode.

2. Description of the Related Art

An organic light emitting display (OLED) among flat panel display devices has a self-emission property, a wide viewing angle, a rapid response speed, a small thickness, a low manufacturing cost, and a high contrast, so it is attracting attention as the next generation flat panel display device.

In general, the organic light emitting display includes a substrate, an anode disposed on the substrate, an emission layer disposed on the anode, and a cathode disposed on the emission layer. In the organic light emitting display, when a voltage is applied between the anode and the cathode, holes and electrons are injected into the emission layer, and the holes and electrons injected into the emission layer are recombined in the emission layer to generate excitons so that light is emitted by energy generated from the excitons that is transitioned from an excited state to a ground state.

The organic light emitting display is classified into a passive matrix type and an active matrix type according to a method of driving pixels disposed in a matrix manner. The passive matrix OLED includes anode and cathode electrodes that cross each other and selectively drives a line, and the active matrix OLED couples a TFT and a capacitor to each indium tin oxide (ITO) pixel electrode to thereby maintain the voltage by capacitance.

In addition, the organic light emitting display is classified into a bottom emission OLED and a top emission OLED according to the direction of emitting light from an organic emission layer. The bottom emission OLED of emitting light toward a substrate includes a reflective electrode formed on the organic emission layer, and a transparent electrode formed under the organic emission layer. In this process, when the organic light emitting display employs the active matrix OLED, the light cannot pass through a portion of the OLED, at which the transistor is formed, so that an area, through which the light can be emitted, is reduced. On the other hand, the top emission OLED includes a transparent electrode formed on the organic emission layer and a reflective electrode formed under the organic emission layer so that the light is emitted in a direction opposite to the substrate to enlarge a light-transmitting area to thereby improve brightness.

In order to realize a full-color OLED, a method of forming respective emission layers on red (R), green (G), and blue (B) pixels has been developed. However, in this case, the emission layers corresponding to the R, G and B pixels have different life spans to make it difficult to maintain white balance when the OLED is driven for a long time. In order to solve the problem, a method has been developed that includes forming an emission layer for emitting a single color of light, and forming a color filter for extracting light corresponding to a predetermined color from the light emitted from the emission layer or a color change medium for converting the light emitted from the emission layer into a predetermined color of light. For example, Korean Patent Laid-open Publication No. 2004-540 discloses an OLED including an organic emission layer for emitting white light, a color filter layer, and a color change medium to extract R, G and B colors.

FIG. 1 is a cross-sectional view of a conventional bottom emission OLED with a color filter layer.

Referring to FIG. 1, the conventional bottom emission OLED includes a transparent substrate 10, a color filter layer 11 (11R, 11G and 11B) formed on the substrate 10, and a passivation layer 12 formed on an entire surface of the color filter layer 11. In addition, a transparent electrode layer 13 is patterned on the passivation layer 12 to be corresponded to the color filter layer 11. A hole transport layer 14, an emission layer 15, an electron injection layer 16, and a bottom electrode layer 17 are formed on the transparent electrode layer 13. In this process, all of the hole transport layer 14, the emission layer 15, and the electron injection layer 16 are organic thin layers, except for the bottom electrode layer 17.

FIGS. 2 and 3 are cross-sectional views of a conventional top emission OLED with a color filter layer.

Referring to FIGS. 2 and 3, a first electrode layer 12 formed of a patterned cathode electrode or anode electrode is disposed on a silicon (SiO₂) or glass substrate 11. After forming the first electrode layer 12, an organic layer 21 is formed. The organic layer 21 includes an organic emitting material 20, which may use a white emitting material or a blue emitting material.

A second electrode layer 16 is disposed on the organic layer 21. The second electrode layer 16 is an anode electrode layer when the first electrode layer 12 is a cathode electrode (see FIG. 2), and the second layer 16 is a cathode electrode layer when the first electrode layer 16 is an anode electrode layer (see FIG. 3). The first electrode layer 12 is formed of a transparent electrode such as ITO or IZO. The organic layer 21 may include a hole injection layer 13, a hole transport layer 19, and an electron transport layer 15, if necessary. When the organic layer 21 includes the hole injection layer 13, the hole transport layer 19, and the electron transport layer 15, and when the first electrode layer 12 is an anode electrode, the organic layer includes the hole injection layer 13, the hole transport layer 19, the organic emitting material 20, and the electron transport layer 15, which are sequentially deposited (see FIG. 2). When the first electrode layer 12 is a cathode electrode layer, they are sequentially deposited in a reverse order (see FIG. 3). In addition, when the first electrode layer 16 is deposited using the anode electrode, the anode electrode is deposited together with a reflective plate (see FIG. 3).

A passivation layer 17 formed of a transparent inorganic material such as SiO₂, Y₂O₃ and so on is deposited on an entire surface of the second electrode layer (16 of FIG. 2 or 12 of FIG. 3) to have a uniform thickness.

Then, a color filter 18′ is disposed on the passivation layer 17 when a white organic emitting material is deposited on the pixel region corresponding to the conventional R, G and B pixels, or a color change medium (CCM) instead of the color filter 18′ is deposited on the passivation layer 17 when a blue organic emitting material is deposited on the pixel region.

Since the conventional bottom and top emission OLEDs with a color filter layer should perform a process of forming the color filter layer on an upper or lower glass due to the position of the color filter layer, when the color filter layer is adhered, alignment margin between upper and lower substrates becomes smaller to make the process complicated and the top and bottom emission difficult. In addition, the passivation layer is deposited on a thin film transistor to make the process complicated.

### SUMMARY OF THE INVENTION

The present invention, therefore, provides an organic light emitting display (OLED) and a method of fabricating the same capable of simplifying a process by forming a color filter layer between an upper portion of a thin film transistor and a first electrode, without a passivation layer, increasing process stability by increasing alignment margin between upper and lower substrates when the color filter layer is adhered, and facilitating top and bottom emission.

In an embodiment of the present invention, an organic light emitting display includes: a substrate having a plurality of pixel regions; a thin film transistor formed at each pixel region of the substrate and including a semiconductor layer, a gate electrode, and source and drain electrodes; a color filter layer formed on the transistor at each pixel region; a first electrode patterned to be in contact with one of the source and drain electrodes of the thin film transistor through a via-hole in the color filter layer; a pixel defining layer having an opening formed to expose a portion of the first electrode; an emission layer formed on the exposed first electrode; and a second electrode formed on the emission layer over the substrate.

In another embodiment according to the present invention, a method of fabricating an organic light emitting display includes: providing a substrate having a plurality of pixel regions; forming a thin film transistor formed at each pixel region of the substrate and including a semiconductor layer, a gate electrode, and source and drain electrodes; forming a color filter layer on the transistor at each pixel region; patterning a first electrode to be in contact with one of the source and drain electrodes of the thin film transistor through a via-hole in the color filter layer; forming a pixel defining layer having an opening for exposing a portion of the first electrode; forming an emission layer on the exposed first electrode; and forming a second electrode on the emission layer all over the substrate.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention:

FIG. 1 is a cross-sectional view of a conventional bottom emission OLED with a color filter layer;

FIG. 2 is a cross-sectional view of a conventional top emission OLED with a color filter layer;

FIG. 3 is a cross-sectional view of another example of a conventional top emission OLED with a color filter layer;

FIG. 4 is a cross-sectional view of a bottom emission OLED with a color filter layer in accordance with a first embodiment of the present invention; and

FIG. 5 is a cross-sectional view of a top emission OLED with a color filter layer in accordance with a second embodiment of the present invention.

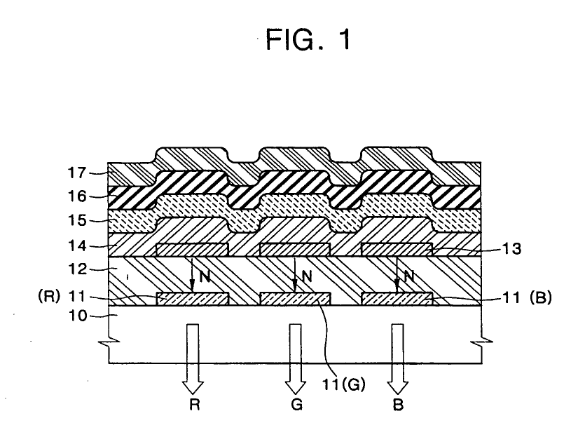

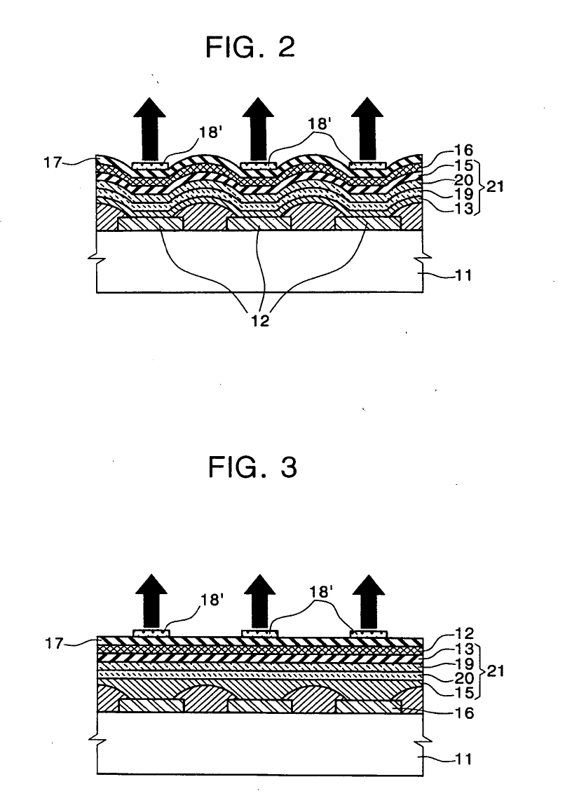

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

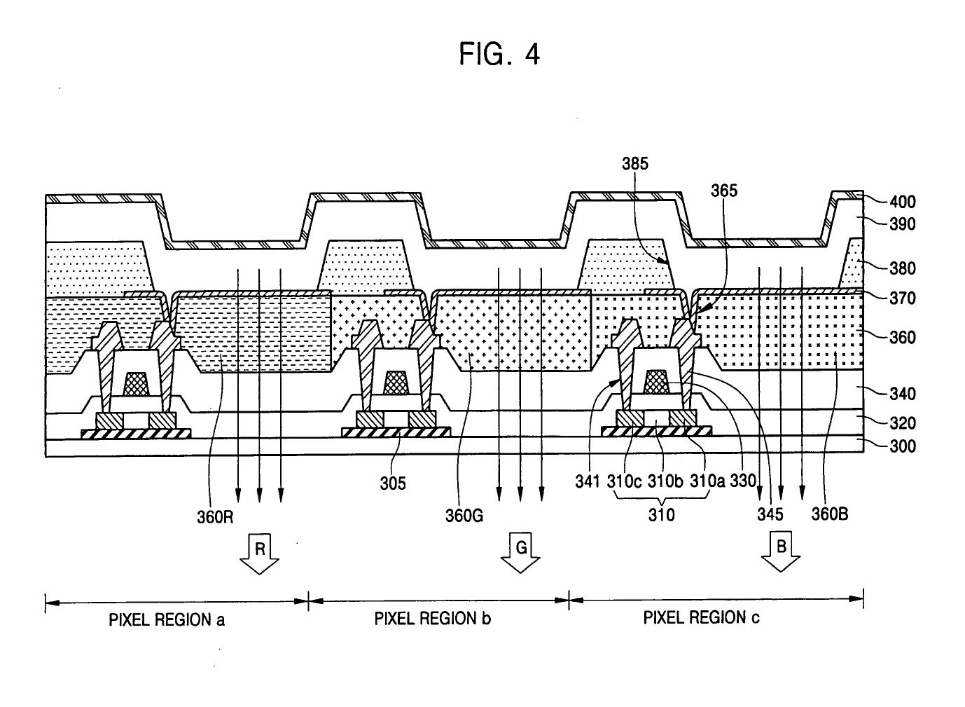

FIG. 4 is a cross-sectional view of a bottom emission OLED with a color filter layer in accordance with a first embodiment of the present invention.

Referring to FIG. 4, in the bottom emission OLED with a color filter layer in accordance with a first embodiment of the present invention, black matrixes 305 spaced apart from each other are formed on a substrate 300 having R, G and B pixel regions a, b and c. The black matrixes 305 function to absorb external light and diffused light. More specifically, the black matrixes 305 are formed in order to prevent color mixing between adjacent color filter layers due to reflection of light caused by a metal interconnection such as a gate electrode and source and drain electrodes, as the light is extracted from the color filter layers of R, G and B pixels during the bottom emission. The black matrix 305 is formed of a metal material such as a Cr and Cr/CrOx, or an organic layer such as resin. The metal material is deposited by a sputtering method, and the organic layer is deposited by a vacuum deposition method or a spin coating method.

Next, a semiconductor layer 310 having source and drain regions 310a and 310c and a channel region 310b is formed in each of the pixel regions a, b and c on the black matrixes 305. The semiconductor layer 310 may be formed of amorphous silicon or polycrystalline silicon, preferably polycrystalline silicon.

After depositing the amorphous silicon using a chemical vapor deposition (CVD) method, the amorphous silicon is crystallized and then patterned to a polysilicon layer using a crystallization method, thereby completing the semiconductor layer 310. The CVD method may use a PECVD or LPCVD method. At this time, when the amorphous silicon is deposited using the PECVD method, after depositing the silicon layer, a dehydrogenation process through heat treatment is performed to decrease the concentration of hydrogen. In addition, the crystallization method of the amorphous silicon layer may employ one of a rapid thermal annealing (RTA) process, a solid phase crystallization (SPC) method, an excimer laser crystallization (ELA) method, a metal induced crystallization (MIC) method, a sequential lateral solidification (SLS) method, and a metal induced lateral crystallization (MILC) method.

Then, a gate insulating layer 320 is formed on an entire surface of the substrate including the semiconductor layer 310. The gate insulating layer 320 may be formed of a silicon oxide layer, a silicon nitride layer or a dual layer thereof, using the PECVD or LPCVD method.

Next, a gate electrode 330 is formed on the gate insulating layer 320 corresponding to a predetermined region of the semiconductor layer 310. The gate electrode 330 is formed of one selected from a group consisting of Mo, W, WSi₂, MoSi₂ and Al, using a sputtering method or a vacuum deposition method.

Then, impurities are injected into the semiconductor layer 310 using a mask to form the source and drain regions 310a and 310c on the semiconductor layer 310, and simultaneously, to define the channel region 310b interposed between the source and drain regions 310a and 310c. The impurities may be selected from one of n and p-impurities. The n-impurities may be formed of one selected from a group consisting of P, As, Bi and Sb (antimony). The p-impurities may be formed of one selected from a group consisting of B, BF, Al, Ga, Ti and In.

Next, an interlayer insulating layer 340 is formed on an entire surface of the substrate including the gate electrode 330. In order to prevent moisture absorption from the exterior, the interlayer insulating layer 340 is formed of a dual layer having an upper layer formed of a silicon nitride (SiNₓ) layer, and a lower oxide (SiO₂) layer, using the PECVD or LPCVD method.

Contact holes 341 are formed in the interlayer insulating layer 340 to exposure the source and drain regions 310a and 310c. A metal layer is deposited on the source and drain regions 310a and 310b and the interlayer insulating layer 340 exposed through the contact holes 341, and then the deposited metal layer is patterned to form source and drain electrodes 345 electrically connected to the source and drain regions 310a and 310c.

As described above, the thin film transistor, which is formed on each of the pixel regions a, b and c, includes the semiconductor layer 310, the gate electrode 330, and the source and drain electrodes 345.

Then, a color filter layer 360 is formed on the thin film transistor of each of the pixel regions a, b and c. In the present invention, the color filter layer 360 is formed at a position of the conventional passivation layer, and the pixel regions includes a red pixel region a, a green pixel region b, and a blue pixel region c. A red color filter layer 360R is formed in the red pixel region a, a green color filter layer 360G is formed in the green pixel region b, and a blue color filter layer 360B is formed in the blue pixel region c. The color filter layer 360 also functions as an insulating layer between the thin film transistor and a first electrode to be formed in the following process.

In addition, each of the color filter layers 360R, 360G and 360B may include pigment, polymer binder, and a functional monomer, in addition to acryl resin as a supporter, each of which can be classified into the red color filter layer 360R, the green color filter layer 360G and the blue color layer 360B depending on the kind of pigment representing a color. Light emitted from an emission layer to be formed in the following process passes through the red color filter layer 360R, the green color filter layer 360G and the blue color layer 360B to transmit a red wavelength of light, a green wavelength of light, and a blue wavelength of light, respectively. At this time, the components have colors of R, G and B. The polymer binder protects a liquid monomer from a developing agent, and controls reliability characteristics such as stabilization of pigment dispersion, and thermal resistance, optical resistance, chemical resistance, and so on of R, G and B patterns. The pigment diffuses the light toward organic particles having good optical and thermal resistance, and has high transparency and good dispersion characteristics as the particles have a smaller size.

In the present invention, the color filter layer is formed to a thickness of 1.0˜2.5 μm using deposition. When the color filter layer has a thickness smaller than 1 μm, color purity is lowered, and when larger than 2.5 μm, crystals of the pigment may be extracted, or the color filter layer or the color filter may have cracks.

The color filter layer 360 may be formed using a pigment dispersion method or a dye method, but not limited thereto. Preferably, the color filter layer 360 is formed using the pigment dispersion method. The pigment dispersion method is a method of fabricating R, G and B color filters by repeating a series of steps of coating an optical polymerization composition having a coloring agent on a transparent substrate, exposing a desired pattern, and removing the unexposed portion using a solvent to thermally harden the unexposed portion. The pigment dispersion method has been widely used in the manufacture of the color filter, since the pigment dispersion method can improve thermal resistance and durability, which are the most important characteristics of the color filter, and maintain a uniform thickness of the layer.

The color filter layer 360 is formed directly on the thin film transistor so that alignment margin between upper and lower substrates during an encapsulation process becomes larger to increase process stability, and a passivation layer can be omitted to simplify the process.

Then, a first electrode 370 is formed at each of the pixel regions a, b and c on the color filter layer 360 through a via-hole 365 to be in contact with one of the source and drain electrodes 345 of the thin film transistor.

When the first electrode 370 is an anode electrode, the first electrode 370 is formed of a transparent electrode such as indium tin oxide (ITO) or indium zinc oxide (IZO), and when a cathode electrode, the first electrode 370 is made of a small thickness of transmission electrode formed of one selected from a group consisting of Mg, Ca, Al, Ag and an alloy thereof. The first electrode 370 may be an electrode capable of emitting light, preferably, formed of ITO.

The first electrode 370 is formed by a sputtering method, an ion plating method, and an evaporation method, preferably the sputtering method. After the deposition of the first electrode 370, the first electrode 370 is patterned by a wet etching process of selectively removing using a pattern such as photoresist (PR) formed through a photolithography process. The wet etching process of patterning the first electrode 370 prevents damage of the color filter using an etchant having a large etch rate with respect to the first electrode 370 and the color filter layer 360.

Then, a pixel defining layer (PDL) 380 having an opening 385 for exposing a portion of the first electrode 370 is formed on the first electrode 370. Generally, the pixel defining layer 380 is formed of one organic material selected from a group consisting of polyimide (PI), polyamide (PA), acryl resin, benzocyclobutene (BCB) and phenolic resin, using a spin coating method.

Next, an emission layer 390 is formed on the exposed first electrode 370 of the substrate. The emission layer 390 is formed to emit a single color of light, which may be white light or blue light, preferably, the white light.

When dopant and emitting materials having different colors are added, the emission layer 390 can obtain white light by mixing PBD, TPD, Counmarin6, DCM1, and Nile red with a PVK polymer in an appropriate ratio. The emission layer 390 can obtain white light by mixing two different emitting materials and then adding the other emitting material. For example, a red emitting material and a green emitting material are mixed, and then a blue emitting material is added, thereby obtaining a white emitting material. The red emitting material is formed of one selected from a group consisting of a small molecule material such as BSA-2, a polymer such as polythiophene (PT), and its derivatives. The green emitting material is formed of one selected from a group consisting of a small molecule material such as Alq3, BeBq2 and Almq, a polymer such as poly(p-phenylevinylene) (PPV), and its derivatives. The blue emitting material is formed of one selected from a group consisting of a small molecule material such as ZnPBO, Balq, DPVBi and OXA-D, a polymer such as polyphenylene (PPP), and its derivatives.

The organic emission layer includes a hole transport compound, an electron transport compound, or a host material as their mixture. The organic emission layer has functions of injecting holes and electrons, transporting the holes and electrons, and generating excitons by recombining the holes and electrons, and can include an electronically neutral compound. The hole transport compound used as the host material of the organic emission material may be triazole derivatives, imidazole derivatives, phenylenediamine derivatives, arlyamine derivatives, and aromatic tertiary amine, preferably tetraaryl benzidine compound (triaryldiamine or triphenyldiamine (TPD)) of triphenyldiamine derivatives. The electron transport compound used as the host material of the organic emission material may be preferably tris(8-quinolinato)aluminum (Alq3).

Preferably, the organic emission layer has a structure that a fluorescent dopant is doped to the hole transport compound, the electron transport compound, or the host material as their mixture. In the present invention, preferably, the fluorescent material contained in the dopant may be at least one compound selected from a group consisting of a rubrene compound, a coumarin compound, a quinaclydon compound, and a dicyanomethylpillane compound. As a minor amount of dopant is added, luminous efficiency and durability can be improved. The emission layer 390 is deposited using the evaporation or spin coating method.

Meanwhile, when the emission layer is a blue emission layer, a blue color change medium is formed instead of the color filter layer.

The color change medium may include a fluorescent material and a polymer binder. The fluorescent material is excited by light incident from the emission layer and transitioned to a ground state to emit light with a wavelength longer than the incident light, which may be classified into a red color change medium for changing the incident light into red light, a green color change medium for changing the incident light into green light, and a blue color change medium for changing the incident light into blue light, depending on the kind of the fluorescent material. The color change mediums may be formed by a pigment dispersion method or a dye method, but not limited thereto. Preferably, the pigment dispersion method of repeatedly performing exposure and development is used.

Next, a second electrode 400 is formed on the emission layer 390. When the first electrode 370 is an anode electrode, the second electrode 400 is formed of one selected from a group consisting of Mg, Ca, Al, Ag, and an alloy thereof, and when the first electrode 370 is a cathode electrode, the second electrode 400 is formed of an anode electrode. Preferably, the second electrode 400 is formed of Al or MgAg.

Then, the substrate at which the second electrode 400 is formed is adhered and encapsulated to an upper substrate to complete the bottom emission active matrix OLED.

As a result, in driving the OLED, the emission layer 390 emits white light. The white light emitted from the emission layer 390 is extracted to the exterior through the transparent first electrode 370 and the transparent substrate 300. At this time, the color filter layers 360R, 360G and 360B are located on a path passing through the light extracted to the exterior from the white emission layer 390. Therefore, when the OLED is driven, the white light emitted from the emission layer 390 is extracted to the exterior through the red color filter layer 360R, the green color filter layer 360G, and the blue color filter layer 360B. As a result, the OLED can realize a full color display of R, G and B colors.

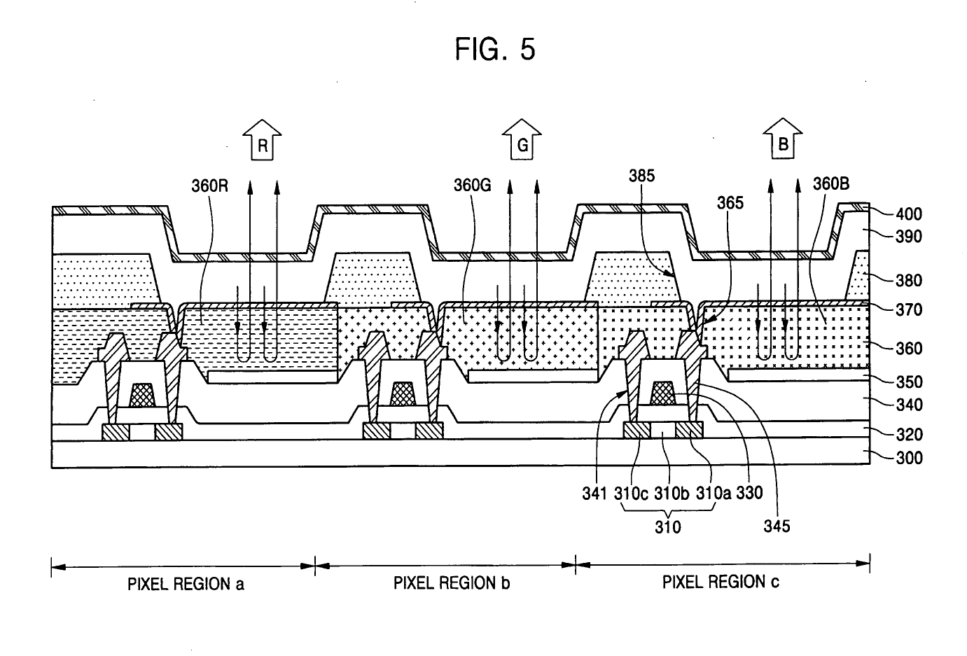

FIG. 5 is a cross-sectional view of a top emission OLED with a color filter layer in accordance with a second embodiment of the present invention.

Referring to FIG. 5, the top emission white active matrix OLED includes a semiconductor layer 310 having source and drain regions 310a and 310c and a channel region 310b, a thin film transistor including a gate electrode 330 and source and drain electrodes 345 connected to the source and drain regions 310a and 310c through contact holes 341, a gate insulating layer 320, and an interlayer insulating layer 340, which are sequentially formed on a substrate 300 having pixel regions a, b and c, using the same method as FIG. 4.

Then, a reflective layer 350 is formed between the interlayer insulating layer 340 and color filter layers 360R, 360B and 360B at a region corresponding to a first electrode 370. The reflective layer 350 is formed of one selected from a group consisting of Al, Ag, Ni, Pd, Pt and an alloy thereof, which has high reflectivity characteristics.

Next, the first electrode 370 is formed on the color filter layers 360R, 360G and 360B to be connected to the source and drain electrodes 345 through via-holes 365. A pixel defining layer (PDL) 380 having an opening 385 for exposing a portion of the first electrode 370 is formed on the first electrode 370. Generally, the pixel defining layer 380 is formed of one organic material selected from a group consisting of polyimide (PI), polyamide (PA), acryl resin, benzocyclobutene (BCB) and phenolic resin. Meanwhile, in the top emission OLED having the color filter layers, the pixel defining layer 380 may be used as a black matrix (BM) for absorbing external light and diffused light when light is extracted toward a reverse direction of the substrate, i.e., toward a top surface of the OLED. More specifically, in the case of the top emission OLED, using the black matrix, light can be extracted from the R, G and B color filter layers to prevent colors from being mixed between adjacent color filter layers due to reflection of the light caused by a metal interconnection such as the source and drain electrodes. The black matrix may be formed of a metal material such as Cr, Cr/CrOx, using a sputtering method. An organic layer may be formed using an evaporation or spin coating method.

In addition, a second electrode 400 may be an anode or cathode, and the second electrode 400 is formed of a transparent electrode such as ITO or IZO in the case of the anode, and formed of a transmissive electrode having a small thickness for transmitting light in the case of the cathode.

Then, the substrate at which the second electrode 400 is finally formed is adhered and encapsulated to an upper substrate to complete the bottom emission active matrix OLED.

As a result, in driving the OLED, the emission layer 390 emits white light. The white light emitted from the emission layer 390 passes through the transparent first electrode 370 to be reflected by the reflective layer 350, and then passes through the first electrode 370 again to be extracted to the exterior through the second electrode 400. At this time, the color filter layers 360R, 360G and 360B are located on a path passing through the light extracted to the exterior from the white emission layer 390. Therefore, when the OLED is driven, the white light emitted from the emission layer 390 is extracted to the exterior through the red color filter layer 360R, the green color filter layer 360G, and the blue color filter layer 360B. As a result, the OLED can realize a full color display of R, G and B colors.

As can be seen from the foregoing, the OLED in accordance with the present invention is capable of simplifying the process by forming the color filter layers between the thin film transistor and the first electrode, without a passivation layer, increasing process stability by increasing alignment margin between upper and lower substrates when the color filter layer is adhered, and facilitating top and bottom emission.

In addition, it is possible to maintain white balance after driving for a long time, since a single color emission layer can be used, without forming each of R, G and B emission layers having different life span characteristics.

Although the present invention has been described with reference to certain exemplary embodiments thereof, changes may be made to the described embodiments without departing from the scope of the present invention.

What is claimed is:

1. An organic light emitting display comprising:
a substrate having at least one pixel regions;
a thin film transistor formed at each pixel region of the substrate and including a semiconductor layer, a gate electrode, and source and drain electrodes;
a color filter layer formed on an entire surface of each pixel region;
a first electrode patterned to be electrically connected with one of the source and drain electrodes of the thin film transistor;
a pixel defining layer having an opening formed to expose a portion of the first electrode;
an emission layer formed on the exposed first electrode; and
a second electrode formed on the emission layer.

2. The organic light emitting display according to claim 1, wherein the pixel region comprises a red pixel region, a green pixel region, and a blue pixel region.

3. The organic light emitting display according to claim 2, wherein the red pixel region comprises a red color filter layer, the green pixel region comprises a green color filter layer, and the blue pixel region comprises a blue color filter layer.

4. The organic light emitting display according to claim 1, wherein the color filter layer has a thickness of 0.1˜2.5 μm.

5. The organic light emitting display according to claim 1, wherein the color filter layer comprises a pigment, a polymer binder, and a functional monomer and acryl resin.

6. The organic light emitting display according to claim 5, wherein the color filter layer is formed using one of a pigment dispersion method and a dye method.

7. The organic light emitting display according to claim 1, wherein the emission layer emits a single color of light.

8. The organic light emitting display according to claim 7, wherein the single color of light passes through the color filter layer to emit one of white light and blue light.

9. The organic light emitting display according to claim 7, wherein, further comprising color change medium for changing the single color of light into blue light in place of the color filter.

10. The organic light emitting display according to claim 7, wherein the emission layer comprises red, green and blue emitting materials and emits white color.

11. The organic light emitting display according to claim 1, wherein the emission layer comprises at least one layer of a hole injection layer, a hole transport layer, and an electron transport layer.

12. The organic light emitting display according to claim 1, wherein the first electrode is one of an anode and a cathode.

13. The organic light emitting display according to claim 1, further comprising a black matrix formed on the substrate.

14. The organic light emitting display according to claim 1, further comprising a reflective layer formed under the color filter layer.

15. The organic light emitting display according to claim 14, wherein the reflective layer is formed of one selected from a group consisting of Al, Ag, Ni, Pd, Pt and an alloy thereof.

16. A method of fabricating an organic light emitting display, comprising:
providing a substrate having a plurality of pixel regions;
forming a thin film transistor formed at each pixel region of the substrate and including a semiconductor layer, a gate electrode, and source and drain electrodes;
forming a color filter layer on an entire surface of each of the pixel regions;
patterning a first electrode to be in contact with one of the source and drain electrodes of the thin film transistor through a via-hole in the color filter layer;
forming a pixel defining layer having an opening for exposing a portion of the first electrode;
forming an emission layer on the exposed first electrode; and
forming a second electrode on the emission layer over the substrate.

17. The method according to claim 17, wherein the pixel region comprises a red pixel region, a green pixel region, and a blue pixel region.

18. The method according to claim 17, wherein the red pixel region comprises a red color filter layer, the green pixel region comprises a green color filter layer, and the blue pixel region comprises a blue color filter layer.

19. The method according to claim 18, wherein the color filter layer has a thickness of 0.1˜2.5 μm.

20. The method according to claim 16, wherein the emission layer emits a single color of light.

21. The method according to claim 20, wherein the single color of light passes through the color filter layer to emit one of white light and blue light.

22. The method according to claim 16, wherein the emission layer comprises at least one layer of a hole injection layer, a hole transport layer, and an electron transport layer.

23. The method according to claim 20, wherein the emission layer comprises red, green and blue emitting materials and emits white color.

24. The method according to claim 16, wherein the first electrode is one of an anode and a cathode.

25. The method according to claim 16, further comprising forming a black matrix on the substrate.

26. The organic light emitting display according to claim 16, further comprising forming a reflective layer under the color filter layer.

27. The organic light emitting display according to claim 26, wherein the reflective layer is formed of one selected from a group consisting of Al, Ag, Ni, Pd, Pt and an alloy thereof.

28. The organic light emitting display according to claim 27, wherein the reflective layer is formed on a layer the same as the source/drain electrode.
